(19) United States
(12) Patent Application Publication
(10) Pub. No.: US 2010/0288334 A1
(43) Pub. Date: Nov. 18, 2010

(54) Generating System That Generates Heat and Electricity By Using A Solar Energy

(76) Inventor: Yu-Lin Chu, Tainan City (TW)

Correspondence Address: KAMRATH & ASSOCIATES P.A., 4825 OLSON MEMORIAL HIGHWAY, SUITE 245, GOLDEN VALLEY, MN, 55422, US

(21) Appl. No.: 12/464,276

(22) Filed: May 12, 2009

(51) Int. Cl. H01L 31/058

(52) U.S. Cl. 136/248

(57) ABSTRACT

A generating system includes a generating device (1), a plurality of flow tubes (2) and a mounting frame (3). The generating device includes a housing (11), a solar cell panel (12), a thermal insulation layer (14), a heat conduction layer (13) and a receiving chamber (15). Thus, the generating system is integrated with a building and can function as a part of the building so as to decrease the costs of fabrication and to enhance the outer appearance of the building. In addition, the generating system and the building are integrated to provide a leakproof function.

### BACKGROUND OF THE INVENTION

1. Field of the Invention

The present invention relates to a generating system and, more particularly, to a generating system that generates heat and electricity by using a solar energy.

2. Description of the Related Art

A conventional generating system comprises a generating module including a heat guide board, a generating member, a light reflecting and gathering hood and a water circulation box. However, the light reflecting and gathering hood having a funnel shape easily affects operation of the generating member. In addition, the conventional generating system has a complicated construction with many parts, thereby increasing the costs of fabrication and causing inconvenience in assembly of the generating system.

### BRIEF SUMMARY OF THE INVENTION

The primary objective of the present invention is to provide a generating system that is mounted on the top of the building or surrounds the periphery of the building, so that the generating system is integrated with the building and can function as a part of the building so as to decrease the costs of fabrication and to enhance the outer appearance of the building.

Another objective of the present invention is to provide a generating system, wherein the solar cell panel can convert the solar energy into an electric power and a thermal energy to provide an electric generating function and to provide a heating function.

A further objective of the present invention is to provide a generating system, wherein the generating system and the building are integrated to provide a leakproof function.

A further objective of the present invention is to provide a generating system, wherein the thermal insulation layer of the generating device is located between the housing and the solar cell panel to provide a thermal insulation effect to the building.

A further objective of the present invention is to provide a generating system, wherein the solar cell panel of the generating device is made transparent to expose each of the flow tubes so that the solar light is directly projected onto each of the flow tubes to enhance the heating efficiency of each of the flow tubes.

A further objective of the present invention is to provide a generating system, wherein a carbon dioxide is filled into the receiving chamber of the housing to increase the heating efficiency of each of the flow tubes.

A further objective of the present invention is to provide a generating system, wherein the conducting wire mounted on the solar cell panel is arranged to form a pattern or figure so that the generating device has an outstanding outer appearance so as to enhance the aesthetic quality of the building.

A further objective of the present invention is to provide a generating system, wherein the boosting device is connected with the generating device to increase the pressure in the receiving chamber of the housing so as to increase the heating efficiency of each of the flow tubes.

Further benefits and advantages of the present invention will become apparent after a careful reading of the detailed description with appropriate reference to the accompanying drawings.

### BRIEF DESCRIPTION OF THE SEVERAL VIEWS OF THE DRAWING(S)

FIG. 1 is a top view of a generating system in accordance with the preferred embodiment of the present invention.

FIG. 2 is a side cross-sectional view of the generating system as shown in FIG. 1.

FIG. 3 is a schematic operational view of the generating system as shown in FIG. 2.

FIG. 4 is a side cross-sectional view of a generating system in accordance with another preferred embodiment of the present invention.

FIG. 5 is a top view of a generating system in accordance with another preferred embodiment of the present invention.

FIG. 6 is a side cross-sectional view of a generating system in accordance with another preferred embodiment of the present invention.

FIG. 7 is a schematic operational view of the generating system as shown in FIG. 6.

FIG. 8 is a side cross-sectional view of a generating system in accordance with another preferred embodiment of the present invention.

FIG. 9 is a schematic operational view of the generating system as shown in FIG. 8.

### DETAILED DESCRIPTION OF THE INVENTION

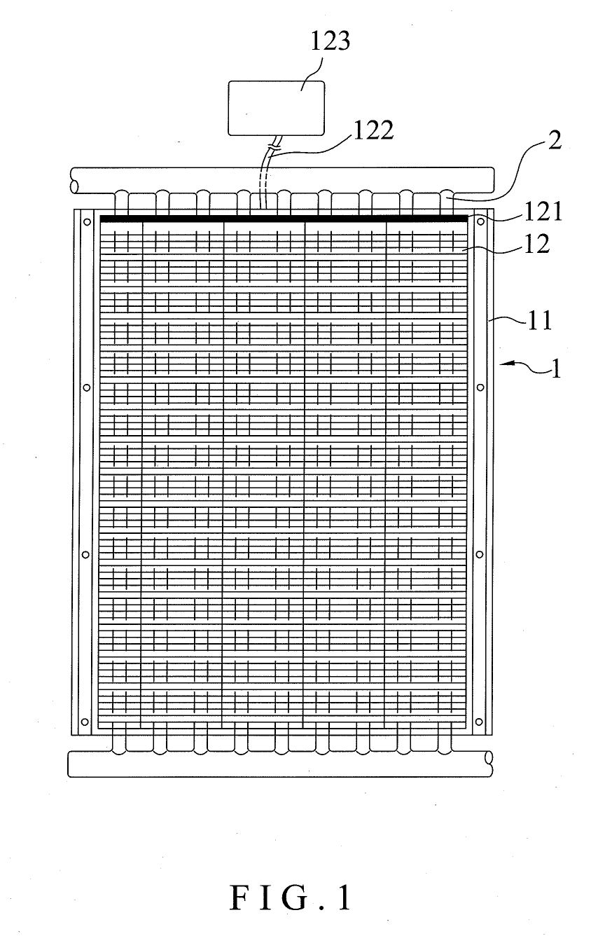

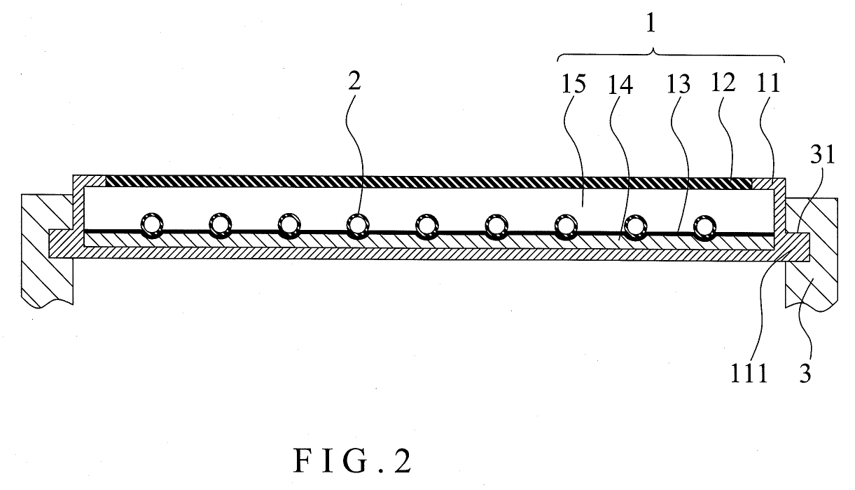

Referring to the drawings and initially to FIGS. 1 and 2, a generating system in accordance with the preferred embodiment of the present invention comprises a generating device 1, a plurality of flow tubes 2 and a mounting frame 3.

The generating device 1 includes a housing 11, a solar cell panel 12 mounted on an upper end of the housing 11 to receive a solar energy and to convert the solar energy into an electric power and a thermal energy, at least one conducting wire 121 mounted on and electrically connected with the solar cell panel 12, an output wire 122 having a first end electrically connected with the conducting wire 121 and a second end electrically connected with a storage unit 123 to transmit the electric power of the solar cell panel 12 into the storage unit 123, a thermal insulation layer 14 mounted in and abutting a bottom of the housing 11, a heat conduction layer 13 mounted in the housing 11 and located above the thermal insulation layer 14, and a receiving chamber 15 formed in the housing 11 and located between the solar cell panel 12 and the heat conduction layer 13 to receive a waste heat produced from the solar cell panel 12.

The housing 11 of the generating device 1 has a substantially U-shaped cross-sectional profile. The thermal insulation layer 14 of the generating device 1 is located between the housing 11 and the solar cell panel 12 to provide a thermal insulation effect and to prevent a heat loss. The thermal insulation layer 14 of the generating device 1 is made of metallic material having a greater heat conduction effect, such as a copper.

Each of the flow tubes 2 is mounted in the receiving chamber 15 of the housing 11 and is placed on the heat conduction layer 13 of the generating device 1. Each of the flow tubes 2 is made of metallic material having a greater heat conduction effect, such as a copper. Each of the flow tubes 2 faces the solar cell panel 12 of the generating device 1.

The mounting frame 3 is mounted outside of and surrounds the housing 11 of the generating device 1 to support the housing 11 of the generating device 1. The mounting frame 3 has a periphery provided with a retaining groove 31, and the housing 11 of the generating device 1 has a periphery provided with a retaining rib 31 inserted into the retaining groove 31 of the mounting frame 3 to lock the housing 11 of the generating device 1 onto the mounting frame 3. Preferably, the mounting frame 3 and the generating device 1 of the generating system are mounted on the top of a building or surround a periphery of the building, so that the mounting frame 3 and the generating device 1 are integrated with the building and can function as a part of the building. In such a manner, the solar cell panel 12 of the generating device 1 faces the solar light and can enhance the outer appearance of the building.

In operation, when the solar cell panel 12 of the generating device 1 receives a solar energy, the solar cell panel 12 can convert the solar energy into an electric power and a thermal energy. Then, the electric power of the solar cell panel 12 is transmitted through the conducting wire 121 and the output wire 122 into the storage unit 123. Thus, the electric power stored in the storage unit 123 can be supplied to the building. In addition, when the solar cell panel 12 converts the solar energy into an electric power, the solar cell panel 12 will produce a waste heat which is filled with the receiving chamber 15 of the housing 11 to heat the flow tubes 2 so as to heat water flowing through the flow tubes 2. At this time, the heat conduction layer 13 of the generating device 1 can enhance the heating efficiency of each of the flow tubes 2 by a heat conduction effect of the heat conduction layer 13. Preferably, the solar cell panel 12 of the generating device 1 is transparent to expose each of the flow tubes 2 outwardly so that the solar light is directly projected onto each of the flow tubes 2 to enhance the heating efficiency of each of the flow tubes 2. In addition, when the water temperature in each of the flow tubes 2 does not reach the required value, the electric power stored in the storage unit 123 can be supplied to heat the water in each of the flow tubes 2.

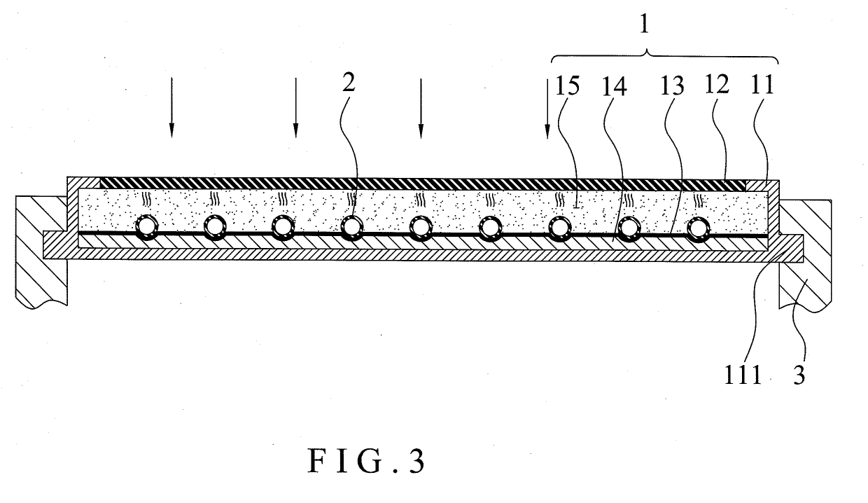

As shown in FIG. 3, a carbon dioxide 5 is filled into the receiving chamber 15 of the housing 11. In such a manner, the carbon dioxide 5 is a gas of the hot house and can encompass the waste heat to decrease the heat loss of the waste heat so that the waste heat is fully distributed in the receiving chamber 15 of the housing 11 to heat each of the flow tubes 2 so as to increase the heating efficiency of each of the flow tubes 2 by provision of the carbon dioxide 5. In addition, when the carbon dioxide 5 is filled into the receiving chamber 15 of the housing 11, the pressure in the receiving chamber 15 of the housing 11 is increased. In such a manner, according to the rule of PV=nRT, wherein P is the pressure, V is the volume and T is the temperature, the volume of the receiving chamber 15 of the housing 11 is a constant so that when the pressure in the receiving chamber 15 of the housing 11 is increased, the temperature in the receiving chamber 15 of the housing 11 is also increased so as to increase the heating efficiency of each of the flow tubes 2.

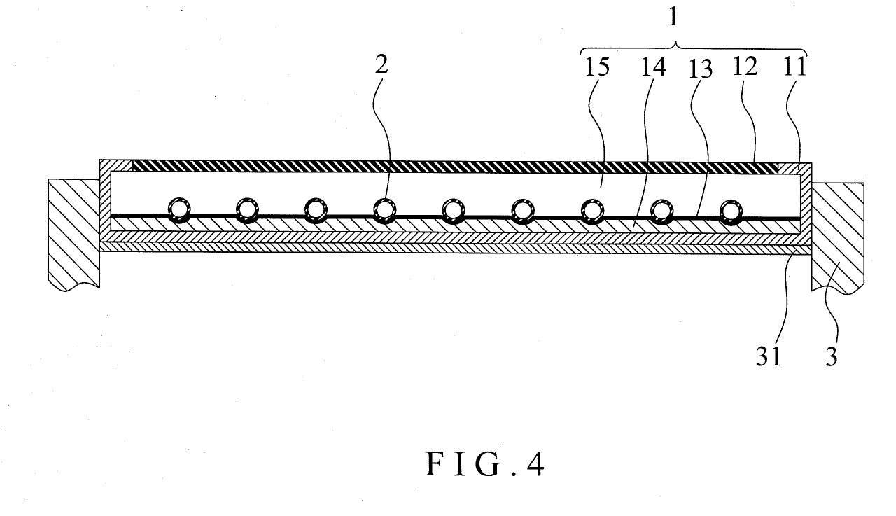

As shown in FIG. 4, the generating system further comprises a support member 31 mounted on the mounting frame 3 and abutting the bottom of the housing 11 to support the generating device 1.

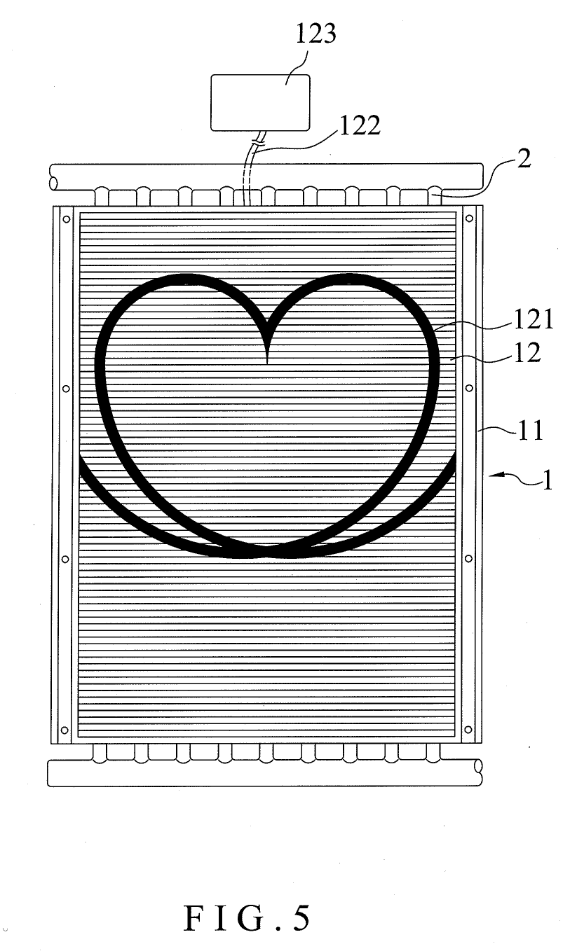

As shown in FIG. 5, the conducting wire 121 mounted on the solar cell panel 12 is arranged to form a pattern or figure so that the generating device 1 has an outstanding outer appearance so as to enhance the aesthetic quality of the building when the generating device 1 is mounted on the outside of the building.

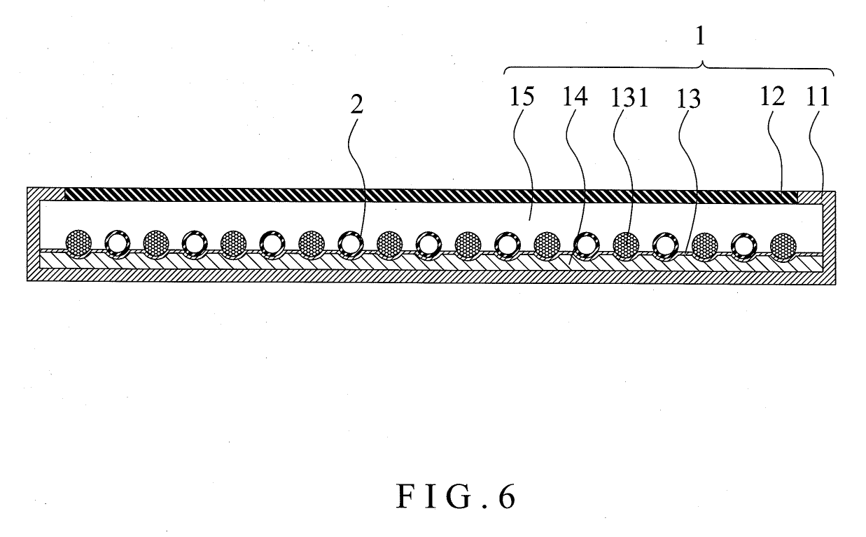

As shown in FIG. 6, the generating system further comprises a plurality of reaction bags 131 mounted in the receiving chamber 15 of the housing 11 and placed on the heat conduction layer 13 of the generating device 1. Each of the reaction bags 131 contains lime stones.

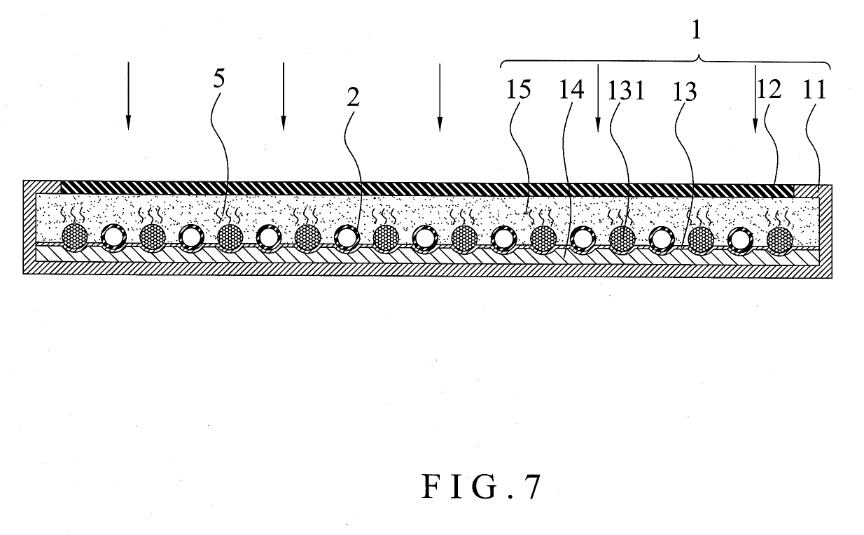

As shown in FIG. 7, when the waste heat produced by the solar cell panel 12 is filled with the receiving chamber 15 of the housing 11 to touch the reaction bags 131, the lime stones in each of the reaction bags 131 will absorb the waste heat and produce a carbon dioxide 5 so as to increase the heating efficiency of each of the flow tubes 2.

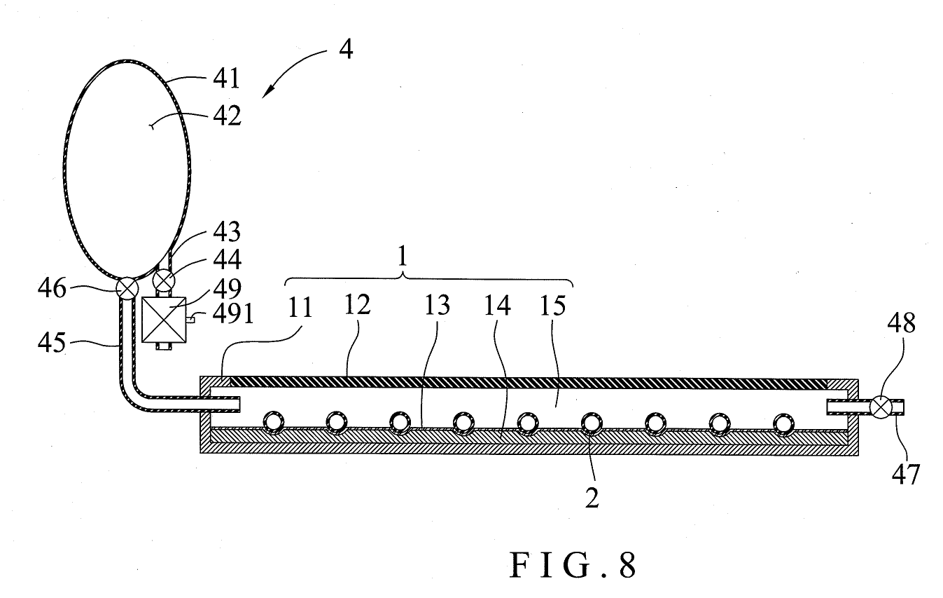

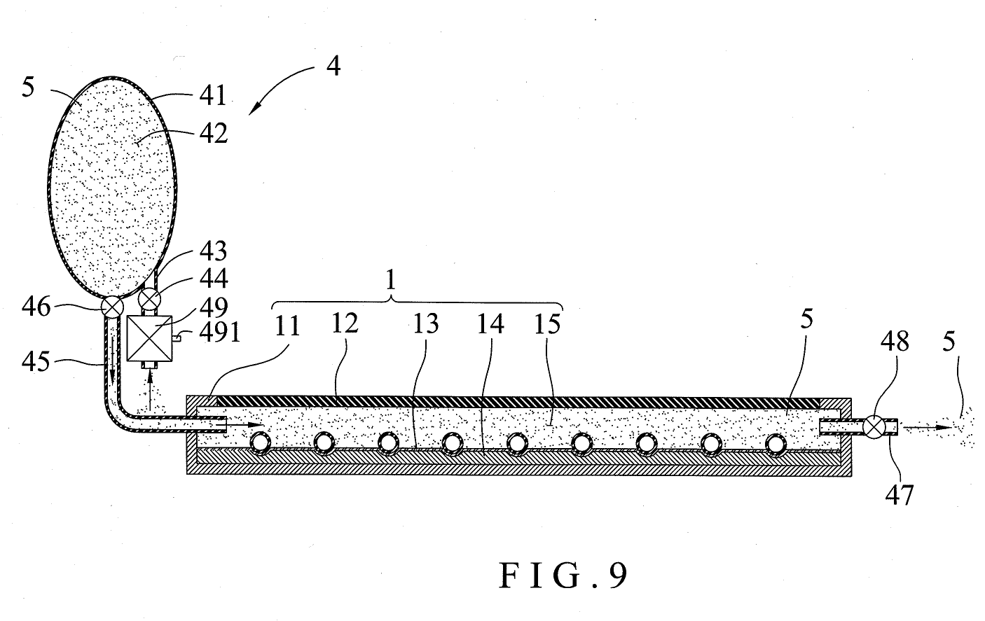

Referring to FIGS. 8 and 9, the generating system further comprises a boosting device 4 connected with the generating device 1 to increase the pressure in the receiving chamber 15 of the housing 11 so as to increase the heating efficiency of each of the flow tubes 2. The boosting device 4 includes a container 41 located outside of the generating device 1 and having an inside provided with a pressure chamber 42, an air inlet pipe 43 connected to the pressure chamber 42 of the container 41 to introduce an ambient air into the pressure chamber 42 of the container 41, an air outlet pipe 45 having a first end connected to the pressure chamber 42 of the container 41 and a second end connected to the receiving chamber 15 of the housing 11 to deliver a pressurized air from the pressure chamber 42 of the container 41 into the receiving chamber 15 of the housing 11, and a pressure release pipe 47 connected to the receiving chamber 15 of the housing 11 to release an excessive air in the receiving chamber 15 of the housing 11 to the ambient environment. The container 41 of the boosting device 4 is made of a metallic shell.

The boosting device 4 further includes a filter 49 that is additionally mounted on the air inlet pipe 43 to filter the air passing through the air inlet pipe 43. The filter 49 of the boosting device 4 has a side provided with a draining portion 491. In such a manner, only a carbon dioxide 5 in the ambient air is allowed to pass through the filter 49 of the boosting device 4 into the pressure chamber 42 of the container 41, and the other gases in the ambient air is drained outwardly from the draining portion 491 of the filter 49. Thus, the carbon dioxide 5 is introduced through the pressure chamber 42 of the container 41 into the receiving chamber 15 of the housing 11 to increase the heating efficiency of each of the flow tubes 2.

The boosting device 4 further includes a first check valve 44 mounted on the air inlet pipe 43 to prevent the air in the pressure chamber 42 of the container 41 from being introduced to the ambient environment, a second check valve 46 mounted on the air outlet pipe 45 to prevent the air in the receiving chamber 15 of the housing 11 from flowing backward into the pressure chamber 42 of the container 41, and a third check valve 48 mounted on the pressure release pipe 47 to prevent the ambient air from being introduced into the receiving chamber 15 of the housing 11.

In operation, when the container 41 of the boosting device 4 is heated by the solar light, the pressure chamber 42 of the container 41 is disposed at a temperature greater than that of the ambient environment. In such a manner, according to the principle of heat convection, the air will flow from a lower temperature zone to a higher temperature zone, so that when the temperature of the pressure chamber 42 of the container 41 is greater than that of the ambient environment, the air in the ambient environment will flow through the air inlet pipe 43 into the pressure chamber 42 of the container 41 automatically. Then, the air in the pressure chamber 42 of the container 41 will flow through the air outlet pipe 45 into the receiving chamber 15 of the housing 11 to accelerate collisions of the air molecules and to increase the efficiency of heat conduction and convection so that the temperature in the receiving chamber 15 of the housing 11 is increased so as to increase the heating efficiency of each of the flow tubes 2. At this time, the pressure release pipe 47 of the boosting device 4 is used to release the air outwardly to the ambient environment when the air pressure in the receiving chamber 15 of the housing 11 reaches a preset excessive value.

In addition, the first check valve 44, the second check valve 46 and the third check valve 48 of the boosting device 4 can prevent the air from flow backward. In practice, each of the first check valve 44, the second check valve 46 and the third check valve 48 of the boosting device 4 is a temperature controlled valve and is controlled by a preset temperature. For example, the preset temperature of the first check valve 44 is about 70° C., the preset temperature of the second check valve 46 is about 60° C., and the preset temperature of the third check valve 48 is about 50° C. In such a manner, the first check valve 44 is opened when the temperature in the pressure chamber 42 of the container 41 is greater than 70° C. to allow the air in the ambient environment to flow through the air inlet pipe 43 into the pressure chamber 42 of the container 41. At this time, the air can be filtered by the filter 49 of the boosting device 4 so that only the carbon dioxide 5 in the ambient air is allowed to pass through the filter 49 of the boosting device 4 into the pressure chamber 42 of the container 41 so as to increase the heating efficiency of each of the flow tubes 2. In addition, the second check valve 46 is opened when the temperature in the air outlet pipe 45 is greater than 60° C. to allow the air in the pressure chamber 42 of the container 41 to flow through the air outlet pipe 45 into the receiving chamber 15 of the housing 11. In addition, the third check valve 48 is opened when the temperature in the receiving chamber 15 of the housing 11 is greater than 50° C. to allow the air in the receiving chamber 15 of the housing 11 to flow through the pressure release pipe 47 into the ambient environment.

Accordingly, the generating system is mounted on the top of the building or surrounds the periphery of the building, so that the generating system is integrated with the building and can function as a part of the building so as to decrease the costs of fabrication and to enhance the outer appearance of the building. In addition, the solar cell panel 12 can convert the solar energy into an electric power and a thermal energy to provide an electric generating function and to provide a heating function. Further, the generating system and the building are integrated to provide a leakproof function. Further, the thermal insulation layer 14 of the generating device 1 is located between the housing 11 and the solar cell panel 12 to provide a thermal insulation effect to the building. Further, the solar cell panel 12 of the generating device 1 is made transparent to expose each of the flow tubes 2 so that the solar light is directly projected onto each of the flow tubes 2 to enhance the heating efficiency of each of the flow tubes 2. Further, a carbon dioxide 5 is filled into the receiving chamber 15 of the housing 11 to increase the heating efficiency of each of the flow tubes 2. Further, the conducting wire 121 mounted on the solar cell panel 12 is arranged to form a pattern or figure so that the generating device 1 has an outstanding outer appearance so as to enhance the aesthetic quality of the building. Further, the boosting device 4 is connected with the generating device 1 to increase the pressure in the receiving chamber 15 of the housing 11 so as to increase the heating efficiency of each of the flow tubes 2.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

1. A generating system, comprising:
a generating device (1) including:
a housing (11);
a solar cell panel (12) mounted on an upper end of the housing to receive a solar energy and to convert the solar energy into an electric power and a thermal energy;
a thermal insulation layer (14) mounted in and abutting a bottom of the housing;
a heat conduction layer (13) mounted in the housing and located above the thermal insulation layer;
a receiving chamber (15) formed in the housing and located between the solar cell panel and the heat conduction layer to receive a waste heat produced from the solar cell panel;
a plurality of flow tubes (2) each mounted in the receiving chamber of the housing and each placed on the heat conduction layer of the generating device;
a mounting frame (3) mounted outside of and surrounding the housing of the generating device to support the housing of the generating device.

2. The generating system of claim 1, further comprising:
a support member (31) mounted on the mounting frame and abutting the bottom of the housing to support the generating device.

3. The generating system of claim 1, wherein the generating device further includes:
at least one conducting wire (121) mounted on and electrically connected with the solar cell panel;
an output wire (122) having a first end electrically connected with the conducting wire and a second end electrically connected with a storage unit (123) to transmit the electric power of the solar cell panel into the storage unit.

4. The generating system of claim 3, wherein the conducting wire mounted on the solar cell panel is arranged to form a pattern or figure.

5. The generating system of claim 1, further comprising:
a plurality of reaction bags (131) mounted in the receiving chamber of the housing and placed on the heat conduction layer of the generating device.

6. The generating system of claim 5, wherein the each of the reaction bags contains lime stones.

7. The generating system of claim 1, further comprising:
a boosting device (4) connected with the generating device to increase a pressure in the receiving chamber of the housing.

8. The generating system of claim 7, wherein the boosting device includes:
a container (41) located outside of the generating device and having an inside provided with a pressure chamber (42);
an air inlet pipe (43) connected to the pressure chamber of the container to introduce an ambient air into the pressure chamber of the container;
an air outlet pipe (45) having a first end connected to the pressure chamber of the container and a second end connected to the receiving chamber of the housing to deliver a pressurized air from the pressure chamber of the container into the receiving chamber of the housing;
a pressure release pipe (47) connected to the receiving chamber of the housing to release an excessive air in the receiving chamber of the housing to the ambient environment.

9. The generating system of claim 8, wherein the boosting device further includes:
a filter (49) that is additionally mounted on the air inlet pipe to filter the air passing through the air inlet pipe.

10. The generating system of claim 9, wherein the filter of the boosting device has a side provided with a draining portion (491).

11. The generating system of claim 10, wherein only a carbon dioxide (5) in the ambient air is allowed to pass through the filter of the boosting device into the pressure chamber of the container, and the other gases in the ambient air is drained outwardly from the draining portion of the filter.

12. The generating system of claim 8, wherein the boosting device further includes:
a first check valve (44) mounted on the air inlet pipe to prevent the air in the pressure chamber of the container from being introduced to the ambient environment;
a second check valve (46) mounted on the air outlet pipe to prevent the air in the receiving chamber of the housing from flowing backward into the pressure chamber of the container;
a third check valve (48) mounted on the pressure release pipe to prevent the ambient air from being introduced into the receiving chamber of the housing.

13. The generating system of claim 8, wherein the container of the boosting device is made of a metallic shell.

14. The generating system of claim 1, wherein the housing of the generating device has a substantially U-shaped cross-sectional profile.

15. The generating system of claim 1, wherein the thermal insulation layer of the generating device is located between the housing and the solar cell panel to provide a thermal insulation effect and to prevent a heat loss.

16. The generating system of claim 1, wherein the thermal insulation layer of the generating device is made of a copper.

17. The generating system of claim 1, wherein each of the flow tubes is made of a copper.

18. The generating system of claim 1, wherein
each of the flow tubes faces the solar cell panel of the generating device;
the solar cell panel of the generating device is transparent to expose each of the flow tubes outwardly.

19. The generating system of claim 1, wherein
the mounting frame has a periphery provided with a retaining groove;
the housing of the generating device has a periphery provided with a retaining rib inserted into the retaining groove of the mounting frame to lock the housing of the generating device onto the mounting frame.

20. The generating system of claim 1, wherein
the mounting frame and the generating device of the generating system are mounted on the top of a building or surround a periphery of the building;
the mounting frame and the generating device are integrated with the building and can function as a part of the building.
